(19) United States
(12) Patent Application Publication
(10) Pub. No.: US 2006/0251821 A1
(43) Pub. Date: Nov. 9, 2006

(54) Multi-sectioned pulsed detonation coating apparatus and method of using same

(75) Inventor: Shmuel Eidelman, Rockville, MD (US)

Correspondence Address: BANNER & WITCOFF, 1001 G STREET N W, SUITE 1100, WASHINGTON, DC, 20001, US

(73) Assignee: Science Applications International Corporation, San Diego, CA (US)

(21) Appl. No.: 10/969,862

(22) Filed: Oct. 22, 2004

(51) Int. Cl. B05D 1/08; B05B 5/025; C23C 16/00

(52) U.S. Cl. 427/446; 118/722; 118/627

(57) ABSTRACT

A pulsed detonation gun, according to one embodiment, has a first section into which a detonable mixture is injected and a second section into which a coating precursor is injected. A detonable or reactive mixture is formed and ignited in the first section, and the detonation or reaction products expand through the first section and into the second section into contact with the coating precursor. Detonation products containing the coating precursor are discharged through an outlet and contacted with a substrate to produce a coating. The device is particularly useful for coating the inside surfaces of small-diameter tubes and a variety of other difficult-to-reach substrate surfaces.

### FIELD OF THE INVENTION

The present invention is directed to coating technology and, more particularly, to pulsed detonation coating (sometimes also referred to as pulsed thermal spray (PTS)).

### DESCRIPTION OF RELATED ART

Several techniques have been used to implement thermal spray coating. One approach has been High Velocity Oxygen/Fuel System (HVOF), in which solid particles are injected in high velocity gas produced by reaction of oxidizer and a fuel at high pressure. Such systems typically are used for deposition at atmospheric pressure and primarily are used for coating metal alloys and cermets powders with particle sizes larger than about 10 μm. Other thermal spray coating techniques include plasma spray, in which particles are heated and accelerated by high temperature plasma produced by an electric discharge in an inert gas atmosphere. Plasma spray systems have been used for both atmospheric- and low-pressure coatings.

Thermal spray coating also has been implemented by intermittent detonations, e.g., by the use of a detonation gun (D-Gun). D-guns can be used for coating a wide variety of materials, such as metals, cermets, and ceramics. D-guns typically have a relatively long (often about 1 m), fluid-cooled barrel having an inner diameter of about one inch. Typically, a mixture of reactive gases, such as oxygen and acetylene, is fed into the gun along with a comminuted coating material in two phases. The reactive gas mixture is ignited to produce a detonation wave, which travels down the barrel of the gun. The detonation wave heats and accelerates the coating material particles, which are propelled out of the gun onto a substrate to be coated.

The detonation wave typically propagates with a speed of about 2.5 km/sec in the tube and can accelerate the particle-laden detonation products to a velocity of about 2 km/sec. However, coating particles never reach the velocity of detonation products due to inertia. In practice, particle velocities usually are lower than about 900 m/sec. The temperature of the detonation products often reaches about 4000 K. After the coating material exits the barrel of the D-gun, a pulse of nitrogen typically is used to purge the barrel. Newer designs of the D-guns allow operation frequencies of up to about 100 Hz. See, e.g., I. Fagoaga et al., “High Frequency Pulsed Detonation (HFPD): Processing Parameters” (1997).

One example of a gas detonation coating apparatus is illustrated in U.S. Pat. No. 4,669,658 to Nevgod et al. A barrel enclosed in a casing has annular grooves made on an inner surface of an initial portion thereof. A main pipe housing a spark plug and having annular grooves on its inner surface is inserted into the initial portion of the barrel. In operation, a gas supply means is turned on. The apparatus works in cycles, each cycle accompanied by gas flowing into the barrel and the main pipe through tubes, gas conduits, and additional pipes. After the gases fill the barrel, the gas mixture is ignited in each cycle with the aid of the spark plug. The detonation products are said to quickly heat up the walls of the barrel and the annular grooves.

According to Nevgod, the gases flowing into the barrel are heated up in two stages. During the first stage the gases are warmed up in the additional pipes heated up in cycles by the detonation products. The heat insulation tubes are said to prevent the pipes from cooling down. During the second stage, the gases are heated up in the barrel and partially in the main pipe. The annular grooves on the inner cylindrical surface of the initial portion of the barrel, the inner surface of the main pipe and on the inner surface of the cover on the end of the barrel, are said to enhance the efficiency of heat exchange with the gases due to an increase in the heat exchange area and due to gas turbulization. The gases are heated to a temperature approximating that of self-ignition. A plurality of ignition sites is provided to accelerate the burning process.

In current coating devices, the ranges of detonation temperature and pressure are intrinsically limited by the properties of the detonable mixture compositions and concentrations. Typical pressures produced by detonation waves in mixtures of common hydrocarbons and oxygen are on the order of about 50 atm in the detonation wave front (shock wave) and about 15 atm behind the detonation wave front. It is sometimes desirable for material processing to use higher pressures and higher temperatures than those which can be produced by detonation of common hydrocarbon/oxygen mixtures. On the other hand, it is sometimes desirable to process materials at temperatures and pressures that are significantly lower than those typical for detonation waves and detonation products.

### SUMMARY OF THE INVENTION

The present invention is directed to a method and apparatus for producing a coating on a substrate using a pulsed detonation gun. In one embodiment, a pulsed detonation coating apparatus has a first section into which a detonable or reactive mixture is injected. The apparatus has a second section into which a coating precursor is injected. A detonable or reactive mixture is formed and ignited in the first section. The detonation or reaction products expand through the first section and into the second section where they contact the coating precursor. Detonation products containing the coating precursor are discharged through an outlet and contacted with a substrate to produce a coating. The multi-sectioned apparatus can be configured to provide temperature, pressure, and a chemical environment which accommodate desired processing conditions for the coating precursor.

In another embodiment, an object is coated at a reduced standoff between the outlet of a pulsed detonation coating apparatus and the coated surface. Conventional detonation coating generally uses a standoff of 8 to 25 cm. In this embodiment, the standoff can be about 5 cm or less and usually ranges from about 2 mm to about 4 cm, and often ranges from about 3 mm to 3 cm, about 4 mm to 2 cm, or about 5 mm to 1 cm. Such reduced standoffs facilitate coating the inside of tubes, especially at corners, and assures uniform material distribution. The apparatus makes coating at these short standoffs possible because of its small size and because of the small particle sizes that can be used in the coating systems.

In another embodiment, a pulsed detonation apparatus comprises a detonation gun having a smallest characteristic dimension of less than 10 mm, an igniter, and an outlet for discharging detonation products. A detonable mixture containing a coating precursor is formed in the detonation gun, and the detonable mixture is ignited to produce detonation products containing the coating precursor. The coating precursor is discharged through the nozzle and is contacted with the substrate to produce a coating. In this embodiment, the coating material can be injected into a detonation tube together with other components of the detonable mixture. Alternatively, the coating precursor can be injected into a coating precursor processing section having either the same or a different smallest characteristic dimension than that of the detonation tube, as in the previous embodiment.

In yet another embodiment, an amorphous metal alloy is coated on a substrate using a pulsed detonation gun. The method comprises providing a pulsed detonation gun having a detonation chamber, an igniter, and an outlet for discharging detonation products. A detonable mixture is injected in the detonation chamber, and a coating precursor containing a metal alloy which is amorphous, or which becomes amorphous after processing, is injected. The detonable mixture is ignited to produce detonation products, which accelerate the coating precursor through the outlet and into contact with the substrate to produce an amorphous metal alloy coating on the substrate. This technique also can be used for building amorphous coating layers on a preform as a method of producing bulk parts from amorphous materials.

The pulsed detonation gun of the present invention is particularly useful for directly depositing coating material(s) over internal surfaces of tubes and other hard-to-reach surfaces of a substrate, such as the inner surfaces of cylinders, the inner surfaces of converging/diverging shapes, the inner surfaces of rectangular tubes, the inner surfaces of shapes that are partially open, and the inner surfaces of various other non-cylindrical shapes.

The material(s) are deposited by high velocity gas products produced in intermittent detonations or an intermittent injection and deflagration process. The detonation tube and its associated fuel/oxidizer supply lines can be constructed at a sufficiently small scale that allows their insertion into long, small-diameter tubes, and permits their use in coating various other difficult-to-reach surfaces. Of course, the apparatus of the present invention also is useful for coating a wide variety of large-diameter tubes, such as gun barrels, tubes used in oil industries, tubes used in food industries, etc., as well as other large substrates including external surfaces thereof.

The detonation products produced by the pulsed detonation gun accelerate and heat the coating precursor or coating material particles to high kinetic energies, resulting in high quality coating depositions that can provide such properties as corrosion-, erosion-, and wear resistance. Existing thermal spray coating equipment is unsuitable for applying such coatings to the inner surfaces of small-diameter tubes and many other difficult-to-reach surfaces.

### BRIEF DESCRIPTION OF THE DRAWINGS

The present invention will now be described in more detail with reference to preferred embodiments of the invention, given only by way of example, and illustrated in the accompanying drawings in which:

FIG. 1 is a schematic illustration of a pulsed detonation coating apparatus according to one embodiment of the present invention, in which a detonation driver section has a smaller internal diameter than that of a second section into which the coating precursor is injected;

FIG. 2 is a schematic illustration of a pulsed detonation coating apparatus according to another embodiment of the present invention, in which a detonation driver section has a larger internal diameter than that of a second section into which the coating precursor is injected;

FIGS. 3A-3C illustrate several variations for coating nozzles which may be used with the pulsed detonation coating apparatus of the present invention; FIGS. 3A and 3B show alternate showerhead configurations; FIG. 3C illustrates a plurality of adjacent devices having nozzles positioned in different coating positions;

FIG. 4 is an illustration of coating the internal surface of a tube using a pulsed detonation gun having a small-diameter detonation tube and an angled coating nozzle;

FIG. 5 is an illustration of coating the external surface of a tube using a pulsed detonation gun;

FIG. 6 is an illustration of a pulsed detonation coating apparatus in which a detonation driver section has a larger internal diameter than that of a second section into which the coating precursor is injected, and in which the second section is connected to the detonation driver section by a converging/diverging nozzle;

FIG. 7 is an illustration of the device shown in FIG. 6 which also has a valve separating the detonation driver section and the second section in accordance with an alternative embodiment of the present invention;

FIG. 8 is an illustration of a device as shown in FIG. 6 in which the coating precursor is axially injected into the converging/diverging nozzle which connects the detonation driver section and the second section;

FIG. 9 is an illustration of a pulsed detonation coating apparatus which has two coating precursor processing sections in series; and

FIG. 10 is an illustration of a pulsed detonation coating apparatus which has two coating precursor processing sections in parallel.

### DETAILED DESCRIPTION OF THE INVENTION

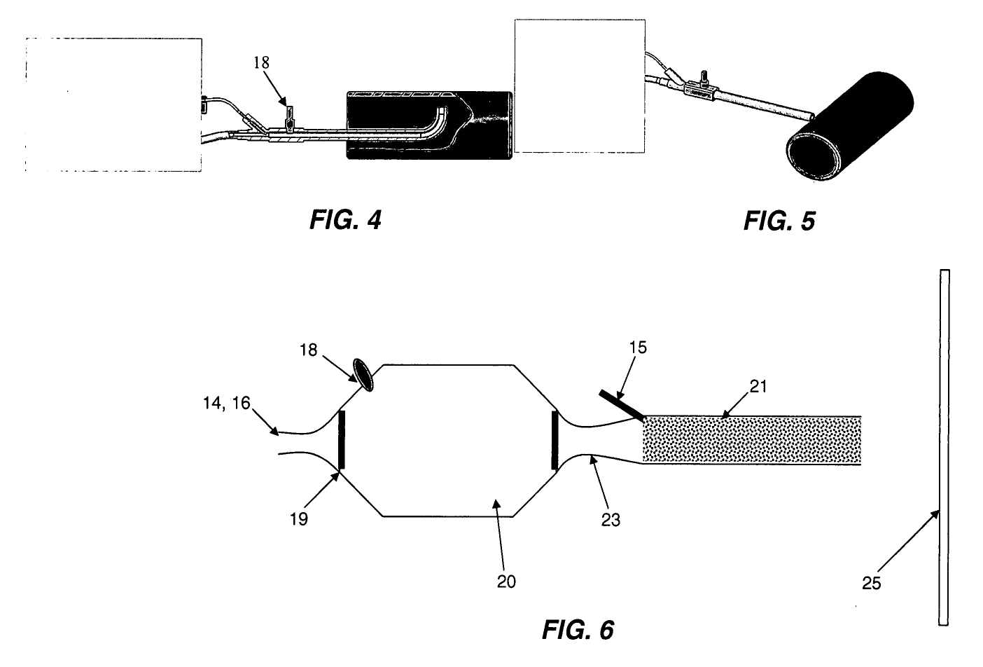

The pulsed detonation coating apparatus of the present invention has utility in applying a wide variety of coating materials to a wide variety of substrates and is particularly useful in coating the inside surfaces of small-diameter tubes, as illustrated in FIG. 4, as well as other difficult-to-reach surfaces, such as the inner surfaces of cylinders, the inner surfaces of converging/diverging shapes, the inner surfaces of small rectangular tubes, the inner surfaces of shapes that are partially open, and the inner surfaces of various other non-cylindrical shapes, to improve such properties as corrosion-, erosion-, and wear resistance. Nanoscale ceramic particles can be used, for example, for coating lightweight, low melting point metals used in aircraft structures to impart erosion- and corrosion resistance. Coatings of polytetrafluoroethylene, polymers, and other plastic materials can be applied to the inside surfaces tubes, for example, for corrosion protection and to improve lubricity and other tribological properties of the inner surfaces of the tubes. Metal and metal composite materials, such us Al/SiC, can be coated on the inner surfaces of cylinders of internal combustion engines. As another example, corrosion/erosion protective materials such as alumina/titania, Cr, WC/Co, Ni and Cr based alloys, and other similar materials can be applied to tubes/pipes used in geothermal energy exploration, which often are subjected to high-temperature corrosive environments. Similar coatings may be applied to tubes/pipes that are used to transport corrosive/erosive liquid, gases, and suspensions used in oil exploration, chemicals industry, and energy generation and energy delivery industries. Thermal barrier coatings based on zirconia, alumina, and similar materials can be applied to metal tubes for protection from very high temperature gas or liquid flow and for reduction of thermal losses. Coatings also can be applied to external surfaces of tubes, as illustrated in FIG. 5, or to any other external surface.

The term “detonation,” “detonation process,” and similar terms are used herein refer to a physical phenomena characterized by a shock wave propagating in front of a reaction front. The shock wave compresses the initial mixture to high pressures and high temperatures so as to initiate a very high rate of reaction behind its front. The detonation front propagates with supersonic speeds, typically on the order of about 1000 to 3000 m/sec.

The term “deflagration process,” as used herein, refers to a combustion process in which a reaction front propagates slowly through the mixture via diffusion and thermal initiation. Combustion of the unconfined mixture does not yield the high pressures that are characteristic of detonation. The combustion front propagates with subsonic speeds, typically on the order of about 1 to 30 m/sec.

The term “detonable mixture,” as used herein, refers to the components present in the detonation driver section at the time detonation is initiated. As discussed herein, in some cases a detonable mixture also is formed in the second section into which the coating precursor is injected. One example of a detonable mixture is oxygen and a fuel detonable in mixtures with oxygen. Another example of a detonable mixture is a monopropellant, such as nitromethane or nitrobenzene. As another example, a detonable mixture can comprise a detonable coating precursor and an oxidizer. The term “reactive mixture” refers to the components present in a volume at the time a deflagration process is initiated.

The term “coating precursor,” as used herein, refers to (1) material that can be heated and accelerated in a detonation process to form a coating, or (2) material that can react during a detonation process or a deflagration process to form a coating material in situ. The coating precursor can comprise, by way of example, particles such as metals, cermets, ceramics, polymers, or combinations thereof. The term “detonable coating precursor,” as used herein, refers to materials which function as both a coating precursor and as a fuel. Non-limiting examples of detonable coating precursors include gaseous and liquid metalorganic compounds, such as silane, disilane, germane, tungsten hexaflurade, trimethylboron, cadmium acetate, magnesium ethoxide, tantalum V-methoxide, tungsten V-ethoxide, zinc naphenate, and zirconium n-butoxide.

The coating precursor may be in a variety of physical forms. For example, the coating precursor may comprise metal particles, which can be pre-mixed with an inert carrier, fuel, or oxidizer before injection into the apparatus. During the detonation process, the coating precursor particles typically are heated and are liquefied or semi-liquefied. The resulting detonation products act as a carrier for the liquefied or semi-liquefied coating precursor, which forms a coating on the substrate. The coating precursor alternatively can be in the gaseous phase, and may form coatings, for example, upon interaction with the substrate via chemical reaction, physical sintering, or both.

Examples of fuels that can be used include, but are not limited to, those detonable in mixtures with oxidizer such as hydrogen, methane, propane, acetylene, or propylene. Also, detonable mixtures of liquid fuels and oxidizer can be used, e.g., kerosene/oxygen, alcohol/oxygen, benzene/oxygen and other similar mixtures. In addition, some detonable monopropellants can be used, such as nitromethane, nitroglycerin, or similar single-component fuels that can be detonated. Selection of a suitable fuel will be apparent to persons skilled in the art.

Non-limiting examples of oxidizers include oxygen, air, mixtures of oxygen and nitrogen, mixtures of oxygen and one or more inert gases such as helium and argon. The relative amounts of nitrogen or inert gases vary over a wide range and can be suitably selected by persons skilled in the art with the aid of no more than routine experimentation. The oxidizer also can be in liquid form. Examples of liquid oxidizers include hydrogen peroxide, nitric acid, hydroxylammonium nitrate, and the like.

For solid coating precursors, the size of particles can vary over a wide range. Often the mean particle size is about 100 μm, 50 μm, or less. Smaller micron particle sizes also can be used, such as those having a mean particle size of less than about 20 μm or 10 μm. Sub-micron sized particles can be used, e.g., having a mean particle size of less than 1 μm, and can have a mean particle size as small as about 100 nm, 10 nm, or less. The coating precursor typically is supplied in an inert liquid or gaseous carrier, such as water, nitrogen, argon, or helium.

The detonation apparatus can be (but is not necessarily) constructed of sufficiently small dimensions to enable the apparatus to easily fit into small-diameter tubes, e.g., tubes having a diameter of about 10 cm, 5 cm, 2 cm or even less. The detonation driver section and second section into which the coating precursor are injected are described herein primarily with reference to cylindrical shapes of which the internal diameter is the smallest characteristic dimension. However, the geometry of the sections is not limited to cylindrical shapes; for example, the detonation driver section and/or the coating precursor processing section may have a rectangular cross-section. In the context of non-cylindrical geometries, the term “diameter” refers to the diameter of a circle having the same area as the cross-sectional area of the non-cylindrical geometry. The diameter of a non-uniform cross-section refers to the diameter of a circle having the same area as the minimum cross-sectional area of the non-uniform section.

The pulsed detonation coating apparatus of the present invention can be (but need not be) constructed substantially smaller than conventional D-guns, permitting its use for coating the inside surface of small-diameter tubes and various other difficult-to-reach substrate surfaces. The pulsed detonation coating apparatus can have a total length of about 200 cm or less. It is contemplated that coating guns of the present invention can have a total length of about 100 cm, 50 cm, 25 cm, 10 cm, 5 cm, 1 cm, or even less. For many applications, substantially larger dimensions can be used effectively. Larger devices may be needed, for example, for effectively coating large substrate surfaces. By way of example, the internal diameter (ID) of the detonation driver section and coating precursor processing section can be about 50 cm, 100 cm, or greater. In smaller devices, the ID of detonation driver and coating precursor sections can be substantially less, such as about 20 mm, about 10 mm, about 5 mm, or about 2 mm or less. By way of example, the ratio of the cross-sectional area, length, or volume of the detonation driver section to the corresponding cross-sectional area, length, or volume of the coating precursor processing section can range from about 100:1 to 1:100, from about 100:1 to 1:1, or from about 1:1 to 1:100.

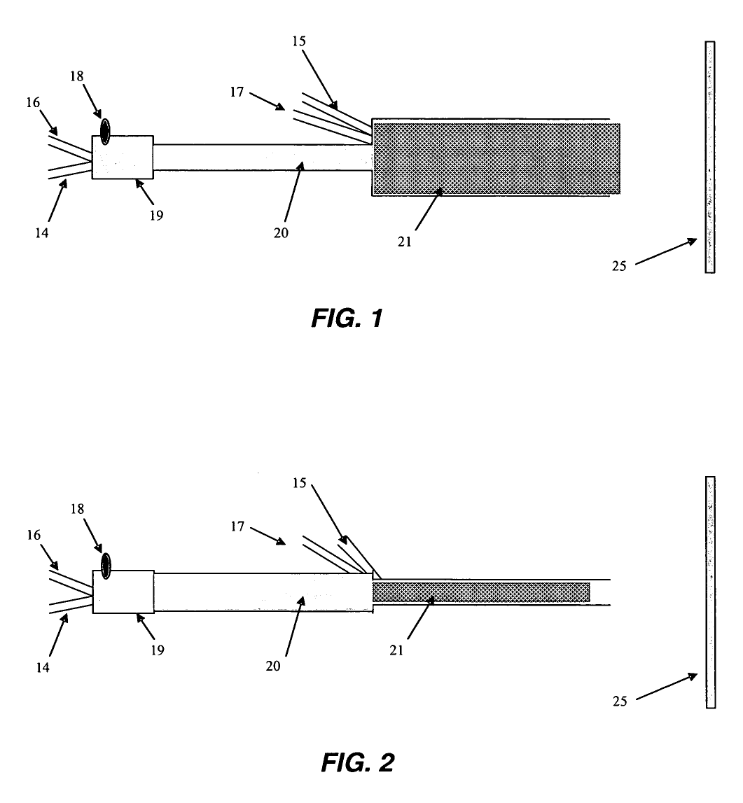

FIG. 1 schematically illustrates a pulsed detonation coating apparatus according to one embodiment of the present invention. The apparatus has a first section which includes an ignition chamber 19 and a detonation driver section 20. The first section alternatively can be continuous instead of having a discrete ignition chamber 19 and detonation driver section 20. A first injector 14 feeds oxidizer into the ignition chamber 19. A second injector 16 feeds fuel into the ignition chamber 19. The oxidizer 14 and fuel 16 injectors each have valves for controlling the flow of oxidizer and fuel, respectively. The ignition chamber 19 also includes a spark plug 18 or other suitable igniter such as a laser, pyrotechnic device, or the like. The coating precursor is injected into a second section 21 which, in this embodiment, has a larger diameter than that of the detonation driver section 20. The coating precursor can be injected through inlet 15, for example, in the form of coating particles suspended in a carrier liquid. A gas, such as an inert gas, can be co-injected through inlet 17 to assist in dispersion of the coating particles in the second section 21. The liquid carrier for the coating precursor can be inert liquid or reactive liquid. Suspensions provide for easy injection and uniform dispersion of the coating particles and help avoid such problems as clogging of the particle injection line, e.g., resulting from particle agglomeration. Smaller particles also tend to be more reactive and thus difficult to handle. For example, sub-micron sized particles of Cu and Ti can self-ignite in air.

One example of a multi-sectioned pulsed detonation coating apparatus has a relatively short 10 cm long×10 cm ID detonation driver section connected to a 10 cm long×50 cm ID coating precursor processing. Such a device is effective for coating large areas, for example, with polytetrafluoroethylene (melting point ˜470 K). The expanding detonation products (typical at 4000 K) from the 10 cm ID detonation driver section into the 50 cm ID coating precursor processing section will allow cooling and prevent overheating of the polytetrafluoroethylene particles, resulting in optimal coating conditions.

FIG. 2 schematically illustrates a device in which the detonation driver section 20 has a larger cross-sectional area and volume compared to the device illustrated in FIG. 1. The second section 21 of the device shown in FIG. 2 has a diameter which is less than that of the detonation driver section 20. The components of the device are as described above with reference to the embodiment of FIG. 1. As discussed below, the dimensions (e.g., diameter and volume) and geometries of the detonation driver section 20 and second section 21, as well as the properties of the materials used, can be manipulated to influence processing conditions.

FIG. 6 illustrates an embodiment in which a generally cylindrical detonation driver section 20 has a length of 8 cm and 5 cm internal diameter. The coating precursor processing section 21 has a length of 10 cm and an internal diameter of 1.6 cm. The detonation driver section 20 is connected to the coating processing section 21 via a converging/diverging nozzle 23. After injection into the detonation driver section 20, the detonable reactants are ignited via igniter 18 which creates a detonation wave. Because of section geometry and the smaller cross section of the converging portion of the nozzle 23, the detonation wave reflects from the detonation driver section walls 20 and elevates pressure in this section to levels that are substantially higher than detonation wave pressure itself. For example, typical pressure in the detonation wave front is about 30 atm. and pressure behind the front about 10 atm. Use of a detonation driver section 20 with a converging nozzle 23 can lead to local peak pressures of about 80 atm and average pressures of about 20 to 30 atm. High pressure detonation products expand through converging/diverging nozzle 23 into coating precursor processing section 21, as shown in FIG. 6, and heat up and accelerate the particles of coating material. Because of the higher pressure in the driver section 20, it is possible to achieve higher pressures and velocities in the second section 21. Also, because of the higher volume of the detonation driver section 20 compared with the volume of second section 21, these processing conditions could be achieved for longer times which will be beneficial, for example, in processing materials with high melting points such as refractory metals, ceramics and cermets.

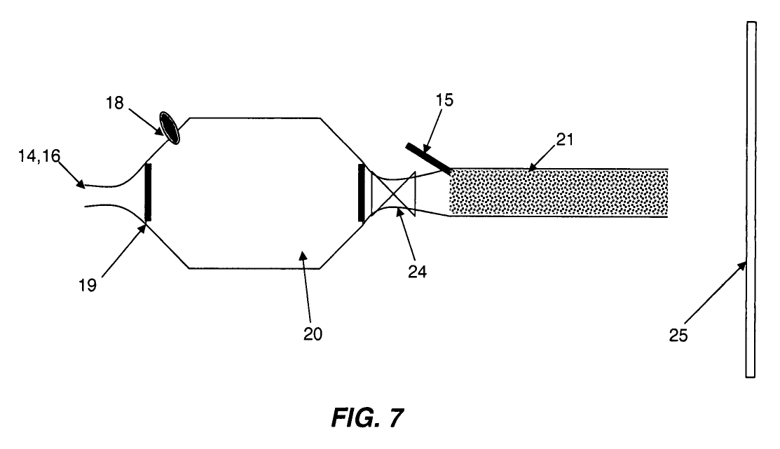

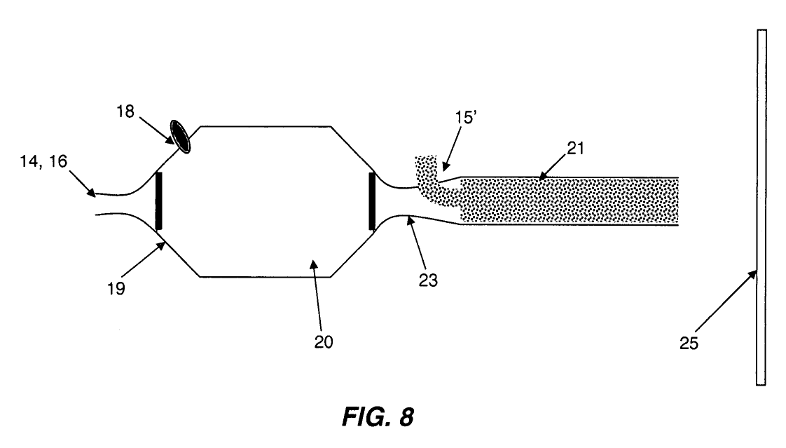

FIG. 7 illustrates another embodiment in which a detonation driver section 20 is connected with the coating precursor processing section 21 through a valve 24 that can be closed during the time the detonable mixture and coating precursor mixture are formed, and then opened during or immediately after detonation is initiated. The valve 24 can be a mechanical valve that opens only when pressure in the detonation chamber exceeds certain values, or a solenoid, piezoelectric or thermofluidic valve, or the like, which is actuated when receiving a control signal. The valve 24 enables substantially higher pressures to be achieved in the detonation driver section 20 without pressure- and/or material loss during the fill process (which can occur, for example, if pressure in the detonation driver section 20 and/or coating processing section 21 is substantially higher than ambient pressure before detonation is initiated). The valve 24 also allows more effective separation between the detonable mixture and coating precursor mixture, which can be important for processing of some materials. For example, nanosized metal particles can easily oxidize when in contact with oxygen that is used as a component of detonable mixture injected in the driver section. Separation of the detonation driver section 20 and coating precursor processing section 21 with a valve 24 helps assure that the metal particles encounter only detonation products after all oxygen is reacted in the detonation process.

Processing at temperatures and pressures significantly lower than those typical for detonation propagating in hydrocarbon/oxidizer mixtures can be facilitated by using suspensions of particles in inert liquid and/or co-injecting with an inert gas (e.g., nitrogen, argon, helium). Alternatively, a reactive carrier liquid and oxidizer gas having relatively low detonation pressure and temperature can be injected through inlets 15 and 17, respectively. Such materials are not easily ignited by the spark ignition (i.e., ignition of the mixture can be avoided). With respect to the apparatus's geometry, a detonation driver section 20 having a relatively small volume and cross-sectional area (e.g., as shown in FIG. 1) results in rapid decay of the shock wave produced during detonation when the shock wave transits to the second section 21, thereby reducing temperature and pressure in the second section 21. Processing at lower temperatures enables use of coating materials with lower melting temperatures, such as polymers, polytetrafluoroethylene, or aluminum alloys. It also allows processing of nanostructure materials that often having lower melting points than bulk materials.

The apparatus also can accommodate processing at higher detonation temperatures and pressures, e.g., using a configuration as shown in FIG. 2. A different detonable mixture can be formed in the second section 21, which creates detonation temperatures and pressures similar to (or possibly even higher than) those created in the detonation driver section 20. There are a number of situations where such an arrangement may be desirable. For example, some detonable mixtures containing particles or other coating precursors are difficult to initiate directly, e.g., with an igniter. In such cases, the detonation wave in the detonation driver section 20 will more readily initiate detonation of a detonable mixture formed in the second section 21. As another example, economics may favor the use of multiple detonable mixtures due to material costs. Another benefit of the configuration shown in FIG. 1 is an increased coating area and coating rate due to the larger volume and cross-sectional area of the second section 21. This larger coating area and coating rate can be achieved without a substantial increase in the overall size of the coating apparatus.

The geometry of the apparatus also can be modified to increase or decrease the time of coating particle exposure to high temperature detonation products created in the detonation driver section 20 (and, if applicable, detonation products created in the second section 21). A shorter second section 21 will reduce particle exposure time. This is beneficial, for example, for processing nanostructure materials that can exhibit grain growth and lose nanostructure and other beneficial properties. In addition, some metastable material phases can be lost due to prolonged exposure to high temperature. For example, amorphous or glassy states of metal alloys can be lost due to overheating. Also, high temperatures can lead to graphitization of diamond, which is a metastable phase of carbon. On the other hand, a longer second section 21 will increase particle exposure time to high temperatures and can be useful, for example, for processing larger particles or materials with high melting points.

The cross-sectional area of the second section 21 also can be varied to increase or decrease temperature and pressure. For example, by reducing the cross-sectional area of the second section 21, as in the embodiment of FIG. 2, the detonation wave produced in the detonation driver section 20 will converge into the second section 21, leading to higher pressures and temperatures than those which would result if the sections 20 and 21 had the same cross-sectional area. The reduced cross-sectional area of the second section 21 also can be used for creating a smaller area coating footprint and/or for coating difficult-to-reach areas.

It sometimes may be advantageous to use a second section 21 that converges to a smaller outlet or diverges to a larger outlet. The ignition chamber 19 can either converge or diverge to the detonation driver section 20 (in the embodiments illustrated in FIGS. 6-10, the ignition chamber 19 diverges into the detonation driver section 20). The walls of the detonation driver section 20 can converge or diverge from the ignition area (or any other point along the section 20) toward the end which adjoins the second section 21. The wall of the second section 21 can be tapered to allow continuous convergence or divergence from the interface with the detonation driver section 20 to the outlet. Another variation is for the coating precursor processing section 21 to diverge and then converge toward the exit of the section 21 to assure uniform exposure of particles to detonation pressure and temperature. Various pulsed detonation engine nozzle configurations which can be used are described in U.S. Pat. No. 6,662,550 B2 to Eidelman et al., the disclosure of which is hereby incorporated by reference. Such nozzle configurations help assure that exposure of the coating precursor material to high pressure, velocity and temperature is more uniform in the coating precursor processing section 21.

As an example of a diverging/converging configuration, the detonation driver section 20 can be generally spherical. The sphere can be connected to a cylindrical second section 21, e.g., via any of the above-described nozzle configurations. The various geometries of the detonation driver section 20 as described above can be used in combination with any of the above-described geometries of the second section 21. For example, both sections 20 and 21 can converge, both sections 20 and 21 can diverge, or both sections 20 and 21 can diverge and then converge. In addition, the detonation driver section 20 can have a bent end which joins the second section 21.

The detonation wave can be made to propagate somewhat faster in a converging configuration and generally will propagate at the same speed in a diverging configuration because it is driven mainly by energy released by chemical reactions. If the detonation wave reflects from a wall when running into a diverging nozzle, it will create higher pressures because most of the kinetic energy of the wave will be transferred into pressure. Thus, converging configurations could be used in the driver section 20 to increase pressure which will create wider shock wave and prolong exposure of the particles in the coating precursor processing section 21 to a high pressure, velocity, and temperature environment. Diverging configuration of the driver section 20 will create narrow shock waves in the coating precursor processing section 21 and will reduce time of exposure of the precursor material to high pressures, velocities and temperatures. The same strategy can be used in the coating precursor processing section 21. Gradually converging nozzles generally will increase the time the coating precursor material is exposed to high pressure, temperature, and velocity conditions. Gradually diverging nozzle generally will decrease the time the coating precursor material is exposed to high pressure, temperature, and velocity conditions.

The injection rates preferably are adjusted so that at the time detonation is initiated, the detonable mixture will mostly fill the detonation driver section 20 and the particle/liquid/gas suspension will mostly fill the second section 20. Usually the components will be co-injected simultaneously, although the components also can be injected sequentially.

Optionally, two or more coating precursors can be alternatively injected into the second section 21. The changing from one coating precursor to another coating precursor can be done at predetermined intervals (e.g., alternating each detonation, every other detonation, every fifth detonation, etc.) or can be actuated manually by an operator. Multiple coating precursors may be used, for example, to create a complex multi-layered coating material on a substrate using a single coating apparatus. When multiple coating precursors are employed, either a single coating precursor processing section can be used or, as discussed below, multiple coating precursor processing sections, e.g., in series or in parallel, can be used.

To help facilitate uniform distribution of coating precursor material inside of coating processing section 21, injection of the coating precursor can be accomplished using an injector 15′ that allows axial injection of coating precursor along the coating processing section 21 volume, as shown in FIG. 8. The injection device 15′ can protrude inside the pulsed detonation gun volume and can be made from refractory materials and/or be thermally insulated to prevent overheating by the detonation products.

The detonable mixture is ignited by suitable igniter, such as a spark plug, laser, pyrotechnic device, or the like. Each detonation creates a detonation wave that propagates through the detonation driver section 20. The resulting high-temperature and high-pressure detonation products heat the coating precursor particles and accelerate the particles through the second section 21. The coating precursor particles are discharged through the detonation tube outlet and toward the inside surface of the substrate 25 to be coated. The frequency of detonations can vary over a wide range and can be suitably selected to meet the needs of a particular application, as will be apparent to persons skilled in the art. The operating frequency most often ranges from about 0.1 to 1,000 Hz.

The intermittent operation of the pulsed detonation coating apparatus avoids the need for separate cooling equipment because intermittent injection of the relatively cold gases between the brief periods of high-temperature detonation enables relatively low temperatures to be maintained in the walls of the detonation driver section 20 and second section 21. Nevertheless, to prevent damage to valves and other system elements, in some cases it may be advantageous to blow air or inert gas through the inner volume of the detonation tube over the valves and other elements of pulsed detonation coating apparatus, or to provide cooling in some other fashion. For example, cooling can be achieved by conventional methods such as circulating water or other cooling medium over external surfaces of the apparatus in specially designed channels.

Because of the intermittent exposure of the internal surfaces of the pulsed detonation apparatus to high temperature detonation products and low temperature injected material, in some cases effective cooling of the apparatus can be facilitated by providing a low thermal conductivity interface between the internal volume of the apparatus and bulk materials of the coating apparatus. In such cases, during the very short time of exposure of the internal volume to high temperature detonation products, only a very minimal amount of heat is transferred to the bulk body of coating apparatus. In practice, this can be implemented by coating the internal surfaces of the apparatus with zirconium oxide, aluminum oxide, or other materials with high thermal stability and low thermal conductivity. Other methods of providing a thermal barrier include inserting low thermal conductivity material into the internal volume or constructing parts exposed to high temperatures out of low thermal conductivity materials. It should be recognized that this technique generally is not effective for coating apparatuses based on continuous operation because it only delays (does not prevent) propagation of the hot front. In fact, this technique actually can increase internal surface temperature during continuous operation because outward heat transfer is restricted.

A coating material can be synthesized in situ during an intermittent detonation or deflagration process. A coating precursor can be pre-mixed with oxidizer or fuel, and the components are co-injected into the second section 21 to form a detonable or reactive mixture. A detonable coating precursor also may be used, and can be co-injected with an oxidizer. When the detonable or reactive mixture is ignited, the coating precursor reacts in the high-temperature detonation or reaction products to yield coating materials that are accelerated through the second section 21, through the outlet and toward the substrate 25 to be coated.

In another embodiment, a pulsed detonation apparatus comprises a detonation gun having a smallest characteristic dimension of less than 10 mm, an igniter, and an outlet for discharging detonation products. For example, the smallest characteristic dimension of the apparatus shown in FIG. 1 is the diameter of the cylindrical detonation driver section 20. A detonable mixture containing a coating precursor is formed in the detonation gun, and the detonable mixture is ignited to produce detonation products containing the coating precursor. The coating precursor is discharged through the nozzle and is contacted with the substrate to produce a coating. The coating material can be injected into a detonation tube together with other components of the detonable mixture, for example using an apparatus having a configuration as described in U.S. Pat. No. 6,787,194 B2, the disclosure of which is hereby incorporated by reference. Alternatively, the coating precursor can be injected into a coating precursor processing section having either the same or a different smallest characteristic dimension than that of the detonation tube, e.g., as in the embodiments shown in FIGS. 1 and 2.

In another embodiment, an amorphous metal alloy is coated on a substrate using a pulsed detonation gun. The method comprises providing a pulsed detonation gun having a detonation chamber, an igniter, and an outlet for discharging detonation products. A detonable mixture is injected in the detonation chamber, and a coating precursor containing a metal alloy that it amorphous (or becomes amorphous after processing) is injected. The detonable mixture is ignited to produce detonation products, which accelerate the coating precursor through the outlet and into contact with the substrate to produce an amorphous metal alloy coating on the substrate. The controlled processing conditions provided by the apparatus enable rapid heating and rapid cooling of the metal alloys, which preserve their amorphous state during detonation and coating. Preferably, the coating precursor is injected into a second section 21 in advance of the detonable mixture formed in the detonation driver section 20, e.g., as illustrated in FIGS. 1 and 2. Coatings of amorphous metal alloys, such as amorphous aluminum alloy, can be used for forming bulk parts by depositing coating amorphous material onto a preform. By avoiding excessively hot coating temperatures, the coating material does not overheat and thus maintains its amorphous phase. Also, further cooling can be accomplished by injecting a cooling material between the detonation/coating cycles. Such cooling material can be liquid or gas that will quickly quench the coating immediately after it is deposited, assuring preservation of the amorphous state. Coatings of the amorphous metal alloy material can be applied continuously or sequentially to form bulk parts, for example, of several millimeters or more in thickness.

Any of the coating processes described herein can be implemented in a vacuum or reduced pressure environment. The lower pressures are particularly useful for coating with small particles and nanosized particles. For example, the substrate 25 can be situated in a low-pressure or vacuum chamber (not shown). The valves, controls, etc. preferably are disposed outside of the vacuum chamber for easy operator access, while the fuel, oxidizer, inert gas/precursor materials, and ignition lines are fed through the wall of the low-pressure or vacuum chamber without interfering with the vacuum or low-pressure environment. A vacuum pump can be used for creating and maintaining low-pressure or vacuum within the low-pressure chamber. The term “low pressure” refers to pressures lower than atmospheric (less than 1 atmosphere) and typically on the order of 10⁻¹ of atmospheres and lower, often on the order of 10⁻² to 10⁻³ atmospheres and lower. The term “vacuum” refers to pressures of 10⁻⁶ atmospheres and lower.

The low pressure environment provides a greater pressure gradient in relation to the detonation pressure, which imparts increased kinetic energy and impact energy to the coating particles, resulting in high quality coatings. The detonation products expand from the high-pressure, high-temperature environment of the detonation driver section 20 and second section 21 to the low-pressure environment of the low-pressure or vacuum chamber. By maintaining low pressure near the substrate 25, it is possible to produce high quality coatings using small-micron scale and even nanoscale-sized particles. The particles are effectively accelerated in the expanding detonation products and do not appreciably decelerate at the substrate because of the very small drag force in the low-density and low-pressure environment. In general, the drag force is smaller for smaller particles. In the low-pressure environment, the characteristic size of smaller (e.g., nanoscale) particles approaches that of the collision free path for molecules of the low-pressure carrying gas. Thus, small-micron size particles generally require lower pressures than do smaller, nanoscale particles for the same drag force at the substrate environment.

In the low-pressure or vacuum chamber, the coating precursor particles are accelerated to high velocities. The particle velocities can vary over a wide range depending on such factors as particle size, detonation pressure, detonation temperature, and the pressure in the low-pressure chamber. Typical particle velocities are in excess of about 2 km/sec., often 3 km/sec., 4 km/sec., 5 km/sec., or even higher. Because the high temperature detonation products heat the coating precursor particles, the coating particles generally are in a liquefied or semi-liquefied state.

The low-pressure environment also effectively removes or reduces the amount of carrier gases from the detonation products as the detonation products are accelerated toward the substrate 25, resulting in relatively low pressure at the substrate surface. This is especially significant for coatings using small-micron and nanosized particles, which are particularly susceptible to being decelerated and diverted away from the substrate by turbulent gas flow in the vicinity of the substrate surface. Such a problem is encountered, for example, in conventional HVOF coating processes.

The detonation reaction produces a brief period of extremely high temperature and high pressure inside the detonation driver section 21. Typical detonation temperatures are on the order of 4000 K, and pressures on the order of 20-30 atmospheres and higher. The period of each detonation most often is less than about 10⁻³ sec. and can be as small as about 10⁻⁴ sec., 10⁻⁵ sec., or even less. Shorter periods of detonation can reduce or avoid appreciable local heating of the substrate, and also can permit operation at high frequencies, e.g., as high as 1000 Hz or higher. Shorter periods of detonation also can help avoid or reduce particle grain growth, particularly with nanosized particles.

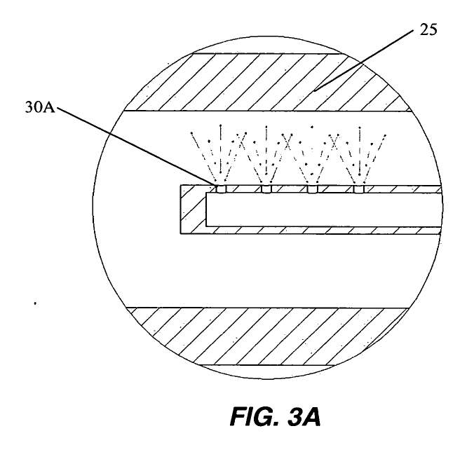

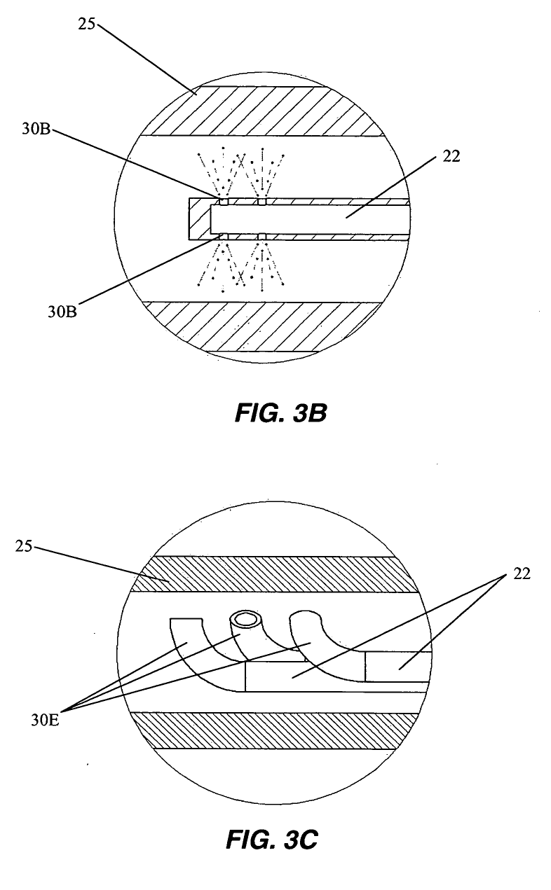

The detonation apparatus outlet may include configured openings and/or a nozzle for directing the detonation products toward the substrate 25 to produce a coating. A wide variety of configurations are possible and may be particularly adapted for coating the inside surfaces of the small-diameter tubes and various other difficult-to-reach portions of substrates, such as the inner surfaces of cylinders, the inner surfaces of converging/diverging shapes, the inner surfaces of small rectangular tubes, the inner surfaces of shapes that are partially open, and the inner surfaces of various other non-cylindrical shapes. Several examples of showerhead and nozzle configurations are illustrated in FIGS. 3A-3C. Other configurations may be suitably selected for coating particular substrates and should be considered to fall within the scope of the present invention. The nozzle can be oriented at a predetermined angle best suited for coating a particular substrate surface, e.g., 0 to 45°, 45 to 90°, or 90 to 135° relative to the axis of the detonation driver section 20 and/or second section 21.

The detonation gun outlet may include a plurality of openings, such as in a “showerhead” type configuration, as illustrated in FIGS. 3A and 3B. FIG. 3A illustrates a plurality of openings 30A located along one side of the detonation gun 22. The apparatus, when placed inside the center of a tube, can coat the inner surfaces of the tube 25 that is opposite to the openings 30A, as illustrated in FIG. 3A. Alternatively, as illustrated in FIG. 3B, a number of openings 30B may be provided at positions along the circumference of the detonation gun 22 to simultaneously coat the entire adjacent inner circumference of the tube 25.

As illustrated in FIG. 3C, a device includes a plurality of pulsed detonation guns, each of which has a structure as previously described. FIG. 3C illustrates three detonation guns 22, each having a nozzle 30E oriented at different predetermined angle. While three guns are illustrated in FIG. 3C, it is contemplated that a multi-gun device may include two, four, or possibly even more guns.

The intermittent detonations advantageously enable the surface of the substrate to cool between coated layers. This enables high deposition rates of coating materials, such as metals or ceramics, onto a wide variety of substrates, especially those, such as plastic, that have low melting point surfaces. If necessary, the surface of the substrate can be subjected to rapid temperature quenching, for example after each detonation exposure or at other suitable intervals. This can be done, for example, by intermittently spraying nitrogen onto the substrate surface between exposures. Quenching can be also achieved by injecting liquids such as water, ethyl alcohol, or inert gases such as helium or argon between the cycles into the detonation driver section 20.

At particle velocities in excess of 2 km/sec., some particles will fuse into coatings, even at low temperatures, and create a strong bond with the substrate surface. Excessive heating of the substrate surface can result in previously coated layers being damaged. By avoiding overheating of the substrate surface, the intermittent detonation process of the present invention permits high quality coatings to be applied at high coating rates.

The multi-section pulsed detonation coating apparatus can have more then one driver section 20 and/or more then one coating precursor processing section 21. Plural driver sections may be desirable, for example, to initiate detonation of a detonable mixture that could not be easily initiated by a spark plug, or to reduce the distance of deflagration-to-detonation transition. For example, an acetylene/oxygen mixture could be used in a first driver section and a methane/air mixture in a second driver section. Detonation of the acetylene/oxygen mixture can be easily initiated by spark discharge, and this detonation wave will propagate into second driver section and initiate detonation of the methane/air mixture. If methane/air mixture is initiated directly with a spark discharge, the transition from deflagration to full detonation wave can take tens of meters. It is contemplated that even more than two detonation driver sections may be desirable to meet the needs of some particular processing conditions.

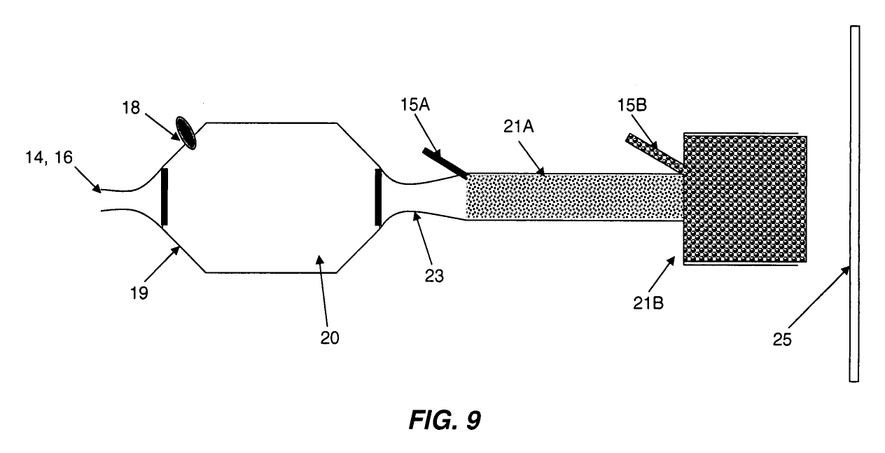

Two or more coating precursor processing sections may be desirable, for example, for creating composite materials where different materials are injected in each section. Use of multiple sections will allow optimization of the environment to which each component of the composite is exposed. The sections could be of different geometry, e.g., different length and cross-sections, to allow greater flexibility of material processing. For example, as shown in FIG. 9, a coating apparatus can have a detonation driver section 20 that connects to smaller diameter first coating processing section 21A and a sequential larger diameter second coating processing section 21B. In the first coating precursor processing section 21A, titanium particles are injected via injector 15A together with detonable gas. In the second coating precursor processing section 21B, an aluminum/inert liquid suspension is injected via injector 15B. Detonation created in the driver section 20 propagates into first processing section where it initiates detonation of the reactive gas/titanium particle suspension. This is effective for heating the titanium particles, which have a relatively high melting point. The shock wave created in the detonation driver section 20 and first coating precursor processing section 21A propagates further into the second coating precursor processing section 21B that contains aluminum particles in inert gas. Aluminum has a relatively low melting point and can be effectively heated by the expanding detonation products in the second processing section 21B. In this configuration, both materials can be deposited onto a substrate 25 at optimal particle temperatures.

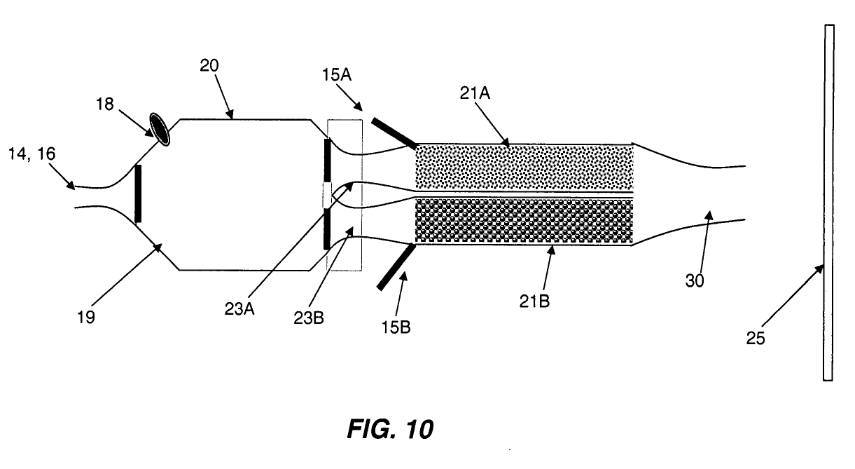

Another variation of a multi-sectioned pulsed detonation gun is shown in FIG. 10. A single detonation driver section 20 is connected with two coating precursor processing sections 21A and 21B which then converge into a single nozzle 30. The coating precursor processing sections 21A and 21B are connected with the detonation driver section 20 with converging/diverging nozzles 23A and 23B, respectively. A detonable mixture is injected into detonation driver section 20 and coating precursors are injected into precursors processing sections 21A and 21B via injectors 15A and 15B, respectively. The coating precursors can be injected simultaneously with injection of the detonable mixture or some time before or after injection of the detonable mixture depending on conditions, volumes, and injection rates. The apparatus shown in FIG. 10 allows processing of two coating precursors at different temperature, velocity, pressure, and chemical environment conditions while forming a composite of the coating materials through a single nozzle and coating onto a substrate 25. For example, one coating precursor processing section 21A can be used for heating titanium in a detonation wave and another section 21B for heating aluminum in an inert medium. Co-deposition of both materials in liquid phase and rapid solidification can result in deposition of an Al—Ti composite with at least one metal is in an amorphous state, leading to substantial improvement of coating material properties. The same apparatus also can be used to form effective coatings of layered composites. In this case, the coating precursor sections can be operated sequentially instead of simultaneously. For example, one section 21A can be used for coating Co—Cr—Al—Y alloy particles that creates a bond coating layer which serves for oxidation protection of turbine blade surfaces. Another section 21B can be used for coating of yttrium-stabilized zirconia (YSZ) that is used for thermal barrier coatings. The Co—Cr—Al—Y alloy layer can be coated first, followed by layers of Co—Cr—Al—Y/YSZ composite with gradual increase in YSZ concentration in layers toward the outer surface. Implementation of this coating technique can be used to optimize both oxidation- and thermal protection.

When plural coating precursor processing sections are used, they may have the same or similar dimensions (e.g., cross-sectional areas, lengths, and volume), or the dimensions may vary significantly. For example, the ratio of the cross-sectional area, length, or volume of one coating precursor processing section to the corresponding cross-sectional area, length, or volume of another coating precursor processing section can range from about 100:1 to 1:100, from about 100:1 to 1:1, or from about 1:1 to 1:100.

While particular embodiments of the present invention have been described and illustrated, it should be understood that the invention is not limited thereto since modifications may be made by persons skilled in the art. The present application contemplates any and all modifications that fall within the spirit and scope of the underlying invention disclosed and claimed herein.

What is claimed is:

1. A method for producing a coating on a substrate comprising:
providing a pulsed detonation coating gun having a first section into which a detonable or reactive mixture is injected, and a second section into which a coating precursor is injected, wherein the first section has a first cross-sectional area and the second section has a second cross-sectional area which is different than the first cross-sectional area;
injecting the coating precursor into the second section;
forming and igniting the detonable or reactive mixture in the first section, wherein detonation or reaction products expand through the first section and into the second section, and wherein detonation products containing the coating precursor are discharged through an outlet and contacted with the substrate to produce a coating.

2. The method of claim 1 wherein the first section comprises an ignition chamber and a detonation driver section, wherein the detonable or reactive mixture substantially fills the ignition chamber and the detonation driver section prior to igniting the detonable or reactive mixture.

3. The method of claim 2 wherein the second cross-sectional area is greater than the first cross-sectional area.

4. The method of claim 2 wherein the second cross-sectional area is less than the first cross-sectional area.

5. The method of claim 2 wherein the second section has a volume which is greater than the volume of the detonation driver section.

6. The method of claim 2 wherein the second section has a volume which is less than the volume of the detonation driver section.

7. The method of claim 1 wherein the coating precursor is co-injected into the second section together with a carrier selected from the group consisting of a reactive liquid, a gaseous or liquid oxidizer, an inert gas, an inert liquid, and combinations thereof, or wherein the coating precursor comprises particles suspended in a liquid which is co-injected with a gas and dispersed in the second section.

8. The method of claim 1 wherein the coating precursor comprises particles selected from the group consisting of metals, cermets, ceramics, polymers, and combinations thereof.

9. The method of claim 8 wherein said particles have a mean particle size of less than about 100 μm.

10. The method of claim 9 wherein said mean particle size is less than about 10 μm.

11. The method of claim 10 wherein said mean particle size is less than about 1 μm.

12. The method of claim 11 wherein said mean particle size is less than about 100 nm.

13. The method of claim 12 wherein said mean particle size is less than about 10 nm.

14. The method of claim 1 wherein said steps of forming and igniting said detonable mixture and injecting said coating precursor are intermittently performed at a frequency of from about 0.1 to about 1,000 Hz.

15. The method of claim 1 further comprising a step of accelerating said detonation products containing said coating precursor in a low-pressure chamber having a pressure of less than 1 atmosphere.

16. The method of claim 15 wherein said low-pressure chamber has a pressure of about 10⁻¹ atmospheres or less.

17. The method of claim 16 wherein said low-pressure chamber has a pressure of about 10⁻³ atmospheres or less.

18. The method of claim 1 wherein the second section comprises at least two coating precursor processing sections into which coating precursors are injected.

19. The method of claim 18 wherein at least two coating precursors are injected substantially simultaneously into the at least two coating precursor processing sections to produce a composite coating.

20. The method of claim 18 wherein at least two coating precursors are injected sequentially into the at least two coating precursor processing sections to produce a layered coating.

21. The method of claim 18 wherein a first coating precursor processing section has a cross-sectional area which is greater than the cross-sectional area of a second coating precursor processing section.

22. The method of claim 18 wherein a first coating precursor processing section has a cross-sectional area which is less than the cross-sectional area of a second coating precursor processing section.

23. The method of claim 18 wherein a first coating precursor processing section has a volume which is greater than the volume of a second coating precursor processing section.

24. The method of claim 18 wherein a first coating precursor processing section has a volume which is less than the volume of a second coating precursor processing section.

25. A multi-sectioned pulsed detonation coating apparatus comprising:
a first section having means for injecting a detonable or reactive mixture and an igniter for igniting the detonable or reactive mixture;
a second section having means for injecting a coating precursor, wherein the first section has a first cross-sectional area and the second section has a second cross-sectional area which is different than the first cross-sectional area; and
an outlet through which detonation products containing the coating precursor are discharged to produce a coating on a substrate.

26. The apparatus of claim 25 wherein the first section comprises an ignition chamber and a detonation driver section, wherein the detonable or reactive mixture substantially fills the ignition chamber and the detonation driver section prior to igniting the detonable or reactive mixture.

27. The apparatus of claim 26 wherein the second cross-sectional area is greater than the first cross-sectional area.

28. The apparatus of claim 26 wherein the second cross-sectional area is less than the first cross-sectional area.

29. The apparatus of claim 26 wherein the second section has a volume which is greater than the volume of the detonation driver section.

30. The apparatus of claim 26 wherein the second section has a volume which is less than the volume of the detonation driver section.

31. The apparatus of claim 26 wherein the detonation driver section and the second section are connected via at least one of a diverging nozzle, a converging nozzle, and a diverging/converging nozzle.

32. The apparatus of claim 26 wherein the detonation driver section is tapered to converge or diverge toward the second section.

33. The apparatus of claim 26 wherein the second section is tapered to converge or diverge toward the outlet.

34. The apparatus of claim 26 wherein the detonation driver section is tapered to converge or diverge toward the second section, and wherein the second section is tapered to converge or diverge toward the outlet.

35. The apparatus of claim 25 further comprising a valve separating the first section and the second section, wherein the valve prevents the detonable or reactive mixture from flowing from the first section into the second section when the valve is in a closed position.

36. The apparatus of claim 25 wherein at least a portion of internal surfaces of the apparatus are coated with a material having high thermal stability and low thermal conductivity.

37. The apparatus of claim 36 wherein the material having high thermal stability and low thermal conductivity is selected from the group consisting of zirconium oxide and aluminum oxide.

38. The apparatus of claim 25 further comprising a low-pressure chamber for accelerating said detonation or reaction products discharged from said outlet, and means for maintaining a pressure of less than 1 atmosphere in said low-pressure chamber.

39. The apparatus of claim 38 wherein said means maintains a pressure not exceeding about 10⁻¹ atmospheres in said low-pressure chamber.

40. The apparatus of claim 39 wherein said means maintains a pressure not exceeding about 10⁻³ atmospheres in said low-pressure chamber.

41. The apparatus of claim 25 further comprising a nozzle configured as a showerhead having a plurality of small openings for directing the coating material toward the substrate.

42. The apparatus of claim 25 which comprises an adjacent plurality of the detonation guns, wherein each detonation gun comprises a nozzle fixed at a predetermined angle relative to the axis of the second section.

43. The apparatus of claim 25 wherein the second section comprises at least two coating precursor processing sections each having means for injecting a coating precursor.

44. The apparatus of claim 43 wherein a first coating precursor processing section and a second coating precursor processing section are in series.

45. The apparatus of claim 43 wherein a first coating precursor processing section and a second coating precursor processing section are in parallel, wherein the first coating precursor processing section and the second coating precursor processing section are connected to the same or to different detonation driver section or sections.

46. The apparatus of claim 44 wherein the first coating precursor processing section has a first cross-sectional area and the second coating precursor processing section has a second cross-sectional area, wherein the ratio of the first cross-sectional area to the second cross-sectional area is from about 100:1 to about 1:100.

47. The apparatus of claim 46 wherein the ratio of the first cross-sectional area to the second cross-sectional area is from about 100:1 to about 1:1.

48. The apparatus of claim 46 wherein the ratio of the first cross-sectional area to the second cross-sectional area is from about 1:1 to about 1:100.

49. The apparatus of claim 44 wherein the first coating precursor processing section has a first volume and the second coating precursor processing section has a second volume, wherein the ratio of the first volume to the second volume is from about 100:1 to about 1:100.

50. The apparatus of claim 49 wherein the ratio of the first volume to the second volume is from about 100:1 to about 1:1.

51. The apparatus of claim 49 wherein the ratio of the first volume to the second volume is from about 1:1 to about 1:100.

52. The apparatus of claim 44 wherein the first coating precursor processing section has a first length and the second coating precursor processing section has a second length, wherein the ratio of the first length to the second length is from about 100:1 to about 1:100.

53. The apparatus of claim 52 wherein the ratio of the first length to the second length is from about 100:1 to about 1:1.

54. The apparatus of claim 52 wherein the ratio of the first length to the second length is from about 1:1 to about 1:100.

55. The apparatus of claim 45 wherein the first coating precursor processing section has a first cross-sectional area and the second coating precursor processing section has a second cross-sectional area, wherein the ratio of the first cross-sectional area to the second cross-sectional area is from about 100:1 to about 1:100.

56. The apparatus of claim 55 wherein the ratio of the first cross-sectional area to the second cross-sectional area is from about 100:1 to about 1:1.

57. The apparatus of claim 55 wherein the ratio of the first cross-sectional area to the second cross-sectional area is from about 1:1 to about 1:100.

58. The apparatus of claim 45 wherein the first coating precursor processing section has a first volume and the second coating precursor processing section has a second volume, wherein the ratio of the first volume to the second volume is from about 100:1 to about 1:100.

59. The apparatus of claim 58 wherein the ratio of the first volume to the second volume is from about 100:1 to about 1:1.

60. The apparatus of claim 58 wherein the ratio of the first volume to the second volume is from about 1:1 to about 1:100.

61. The apparatus of claim 45 wherein the first coating precursor processing section has a first length and the second coating precursor processing section has a second length, wherein the ratio of the first length to the second length is from about 100:1 to about 1:100.

62. The apparatus of claim 61 wherein the ratio of the first length to the second length is from about 100:1 to about 1:1.

63. The apparatus of claim 61 wherein the ratio of the first length to the second length is from about 1:1 to about 1:100.

64. The apparatus of claim 45 wherein the first coating precursor processing section and the second coating precursor processing section are connected to a common nozzle.

65. The apparatus of claim 25 wherein the means for injecting the coating precursor comprises an injector that allows axial injection of coating precursor along the volume of the second section.

66. The apparatus of claim 25 wherein the first section comprises at least two detonation driver sections, each of which has means for injecting a detonable or reactive mixture and an igniter for igniting the detonable or reactive mixture.

67. The apparatus of claim 25 wherein each of the first section and the second section has a diameter of about 100 cm or less.

68. The apparatus of claim 67 wherein the diameter is about 50 cm or less.

69. The apparatus of claim 68 wherein the diameter is about 5 cm or less.

70. The apparatus of claim 69 wherein the diameter is about 1 cm or less.

71. A method for producing a coating on a substrate comprising:
providing a pulsed detonation gun having an igniter, a detonation tube, and an outlet;
forming and igniting a detonable or reactive mixture in the detonation tube, wherein detonation or reaction products containing a coating precursor are accelerated through the detonation tube and discharged through an outlet and contacted with a substrate to produce a coating; wherein the substrate is spaced from the outlet by a standoff of about 5 cm or less.

72. The method of claim 71 wherein the standoff is from about 2 mm to about 4 cm.

73. A pulsed detonation coating apparatus comprising a detonation tube for receiving a detonable or reactive mixture, wherein said detonation tube has a smallest characteristic dimension of less than 10 mm and comprises:
at least one inlet for receiving a detonable or reactive mixture containing at least one coating precursor;
an igniter for igniting said detonable or reactive mixture to produce detonation or reaction products containing said coating precursor; and
an outlet for discharging said coating precursor toward a substrate to produce a coating on the substrate.

74. The apparatus of claim 73 wherein said detonation tube has a smallest characteristic dimension of less than about 5 mm.

75. The apparatus of claim 74 wherein the smallest characteristic dimension is less than about 2 mm.

76. A method of coating amorphous metal alloy on a substrate, the method comprising:
providing a pulsed detonation gun having a detonation chamber, an igniter, and an outlet for discharging detonation products;
injecting a detonable mixture in the detonation chamber;
injecting a coating precursor containing a metal alloy which is amorphous or which becomes amorphous after processing;
igniting the detonable mixture to produce detonation products; wherein the detonation products accelerate the coating precursor through the outlet and into contact with the substrate to produce an amorphous metal alloy coating on the substrate.

77. The method of claim 76 wherein the pulsed detonation gun comprises a first section into which the detonable mixture is injected and ignited, and a second section into which the coating precursor is injected.

78. The method of claim 76 further comprising a step of accelerating said detonation products containing said coating precursor in a low-pressure chamber having a pressure of less than 1 atmosphere.

79. The method of claim 78 wherein said low-pressure chamber has a pressure of about 10⁻¹ atmospheres or less.

80. The method of claim 79 wherein said low-pressure chamber has a pressure of about 10⁻³ atmospheres or less.

81. The method of claim 76 wherein the substrate is a preform and the amorphous coating is applied to the preform to form a bulk part.

82. The apparatus of claim 25 wherein the first section has a first cross-sectional area and the second section has a second cross-sectional area, wherein the ratio of the first cross-sectional area to the second cross-sectional area is from about 100:1 to about 1:100.

83. The apparatus of claim 82 wherein the ratio of the first cross-sectional area to the second cross-sectional area is from about 100:1 to about 1:1.

84. The apparatus of claim 82 wherein the ratio of the first cross-sectional area to the second cross-sectional area is from about 1:1 to about 1:100.

85. The apparatus of claim 25 wherein the first section has a first volume and the second section has a second volume, wherein the ratio of the first volume to the second volume is from about 100:1 to about 1:100.

86. The apparatus of claim 85 wherein the ratio of the first volume to the second volume is from about 100:1 to about 1:1.

87. The apparatus of claim 85 wherein the ratio of the first volume to the second volume is from about 1:1 to about 1:100.

88. The apparatus of claim 25 wherein the first section has a first length and the second section has a second length, wherein the ratio of the first length to the second length is from about 100:1 to about 1:100.

89. The apparatus of claim 88 wherein the ratio of the first length to the second length is from about 100:1 to about 1:1.

90. The apparatus of claim 88 wherein the ratio of the first length to the second length is from about 1:1 to about 1:100.
